(19) United States
(12) Patent Application Publication
(10) Pub. No.: US 2024/0341139 A1
(43) Pub. Date: Oct. 10, 2024

(54) DISPLAY DEVICE

(71) Applicant: Samsung Display Co., Ltd., Yongin-si (KR)

(72) Inventors: BYOUNGKYU PARK, Yongin-si (KR); JAEWON CHOI, Yongin-si (KR)

(21) Appl. No.: 18/539,971

(22) Filed: Dec. 14, 2023

(30) Foreign Application Priority Data
Apr. 5, 2023 (KR) 10-2023-0044823

(51) Int. Cl. H10K 59/131; H10K 50/842; H10K 77/10

(52) U.S. Cl. CPC H10K 59/131; H10K 50/842; H10K 77/111

(57) ABSTRACT

A display device includes: a display panel including a first region, a second region, and a bending region located along a first direction, the bending region being between the first and second regions; a plurality of sensing electrodes on the first region; a data driver on the second region; sensing lines on the first region connected to the sensing electrodes, and extending in the first direction toward opposite sides of the data driver opposite to each other in a second direction crossing the first direction; and a cover layer on the sensing lines.

### CROSS-REFERENCE TO RELATED APPLICATION

The present application claims priority to and the benefit of Korean Patent Application No. 10-2023-0044823, filed on Apr. 5, 2023, in the Korean Intellectual Property Office, the entire content of which is incorporated by reference herein.

### BACKGROUND

### 1. Field

Aspects of embodiments of the present disclosure relate to a display device.

### 2. Description of Related Art

Electronic devices, such as smart phones, digital cameras, notebook computers, navigation systems, and smart televisions, that provide images to users include a display device for displaying the images. The display device includes a display panel for generating an image, and an input device such as an input sensor.

The input sensor is disposed on the display panel, and senses a user's touch. A signal sensed by the input sensor is converted into an input signal. The display panel provides a user with an image in response to the input signal of the input sensor.

The display panel includes a plurality of pixels, a plurality of panel lines connected to the pixels, and a plurality of panel pads connected to the panel lines. The input sensor includes a plurality of sensing electrodes, a plurality of sensing lines connected to the sensing electrodes, and a plurality of sensing pads connected to the sensing lines.

The panel pads and the sensing pads are connected to a timing controller configured to control the operation of the display panel, and an input sensing controller configured to control the operation of the input sensor. The timing controller and the input sensing controller may be mounted on a printed circuit board, and may be connected to the panel pads and the sensing pads.

The above information disclosed in this Background section is for enhancement of understanding of the background of the present disclosure, and therefore, it may contain information that does not constitute prior art.

### SUMMARY

One or more embodiments of the present disclosure are directed to a display device capable of preventing or substantially preventing sensing lines from being corroded by moisture.

According to one or more embodiments of the present disclosure, a display device includes: a display panel including a first region, a second region, and a bending region located along a first direction, the bending region being between the first and second regions; a plurality of sensing electrodes on the first region; a data driver on the second region; sensing lines on the first region connected to the sensing electrodes, and extending in the first direction toward opposite sides of the data driver opposite to each other in a second direction crossing the first direction; and a cover layer on the sensing lines.

In an embodiment, the cover layer may include a silane compound to absorb moisture.

In an embodiment, the display device may further include a driving cover layer covering the data driver and portions of the sensing lines adjacent to the data driver.

In an embodiment, the driving cover layer may be located on the second region.

In an embodiment, an opening may be defined in the driving cover layer; and the opening may overlap with portions of the sensing lines in a plan view.

In an embodiment, the opening may pass through the driving cover layer and the cover layer.

In an embodiment, the opening may be adjacent to the opposite sides of the data driver in a plan view.

In an embodiment, the opening may not overlap with the data driver.

In an embodiment, the driving cover layer may include: an insulating layer on the cover layer; and a cover portion including a black material on the insulating layer.

In an embodiment, the cover layer may be located on the first region, the bending region, and the second region.

According to one or more embodiments of the present disclosure, a display device includes: a display panel including a first region, a second region, and a bending region located along a first direction, the bending region being between the first and second regions; a plurality of sensing electrodes on the first region; a data driver on the second region; sensing lines on the first region connected to the sensing electrodes, and extending in the first direction toward opposite sides of the data driver opposite to each other in a second direction crossing the first direction; and a driving cover layer covering the data driver and portions of the sensing lines adjacent to the data driver. An opening overlapping with portions of the sensing lines in a plan view is defined in the driving cover layer.

In an embodiment, the driving cover layer may be located on the second region.

In an embodiment, the opening may be defined to be adjacent to the opposite sides of the data driver in a plan view.

In an embodiment, the opening may not overlap with the data driver in a plan view.

In an embodiment, the display device may further include a cover layer between the sensing lines and the driving cover layer.

In an embodiment, the cover layer may include a silane compound to absorb moisture.

In an embodiment, the opening may pass through the cover layer and the driving cover layer.

In an embodiment, the cover layer may be located on the first region, the bending region, and the second region.

In an embodiment, the driving cover layer may include: an insulating layer on the data driver; and a cover portion including a black material on the insulating layer.

In an embodiment, when the bending region is bent, a portion located in the bending region of a sensing line from among the sensing lines may be located more inward than other portions of the sensing line located in the first and second regions.

### BRIEF DESCRIPTION OF THE FIGURES

The above and other aspects and features of the present disclosure will be more clearly understood from the following detailed description of the illustrative, non-limiting embodiments with reference to the accompanying drawings, in which:

FIG. 1 is a perspective view of a display device according to an embodiment of the present disclosure;

FIG. 2 is an exploded perspective view of the display device illustrated in FIG. 1;

FIG. 3 is a plan view of a display panel illustrated in FIG. 2;

FIG. 4 illustrates an equivalent circuit of a pixel illustrated in FIG. 3;

FIG. 5 is a cross-sectional view of a portion corresponding to a light-emitting element illustrated in FIG. 4;

FIG. 6 is a plan view of an input sensor illustrated in FIG. 2;

FIG. 7 shows a configuration of a sensing electrode illustrated in FIG. 6;

FIG. 8 is a cross-sectional view taken along the line I-I′ illustrated in FIG. 7;

FIG. 9A is a cross-sectional view taken along the line II-II′ illustrated in FIG. 6;

FIG. 9B illustrates a bent state of a bending region illustrated in FIG. 9A; and

FIG. 10 is a cross-sectional view taken along the line III-III′ illustrated in FIG. 6.

### DETAILED DESCRIPTION

Hereinafter, embodiments will be described in more detail with reference to the accompanying drawings, in which like reference numbers refer to like elements throughout. The present disclosure, however, may be embodied in various different forms, and should not be construed as being limited to only the illustrated embodiments herein. Rather, these embodiments are provided as examples so that this disclosure will be thorough and complete, and will fully convey the aspects and features of the present disclosure to those skilled in the art. Accordingly, processes, elements, and techniques that are not necessary to those having ordinary skill in the art for a complete understanding of the aspects and features of the present disclosure may not be described. Unless otherwise noted, like reference numerals denote like elements throughout the attached drawings and the written description, and thus, redundant description thereof may not be repeated.

When a certain embodiment may be implemented differently, a specific process order may be different from the described order. For example, two consecutively described processes may be performed at the same or substantially at the same time, or may be performed in an order opposite to the described order.

In the drawings, the relative sizes, thicknesses, and ratios of elements, layers, and regions may be exaggerated and/or simplified for clarity. Spatially relative terms, such as “beneath,” “below,” “lower,” “under,” “above,” “upper,” and the like, may be used herein for ease of explanation to describe one element or feature's relationship to another element(s) or feature(s) as illustrated in the figures. It will be understood that the spatially relative terms are intended to encompass different orientations of the device in use or in operation, in addition to the orientation depicted in the figures. For example, if the device in the figures is turned over, elements described as “below” or “beneath” or “under” other elements or features would then be oriented “above” the other elements or features. Thus, the example terms “below” and “under” can encompass both an orientation of above and below. The device may be otherwise oriented (e.g., rotated 90 degrees or at other orientations) and the spatially relative descriptors used herein should be interpreted accordingly.

In the figures, the x-axis, the y-axis, and the z-axis are not limited to three axes of the rectangular coordinate system, and may be interpreted in a broader sense. For example, the x-axis, the y-axis, and the z-axis may be perpendicular to or substantially perpendicular to one another, or may represent different directions from each other that are not perpendicular to one another.

It will be understood that, although the terms “first,” “second,” “third,” etc., may be used herein to describe various elements, components, regions, layers and/or sections, these elements, components, regions, layers and/or sections should not be limited by these terms. These terms are used to distinguish one element, component, region, layer or section from another element, component, region, layer or section. Thus, a first element, component, region, layer or section described below could be termed a second element, component, region, layer or section, without departing from the spirit and scope of the present disclosure.

It will be understood that when an element or layer is referred to as being “on,” “connected to,” or “coupled to” another element or layer, it can be directly on, connected to, or coupled to the other element or layer, or one or more intervening elements or layers may be present. Similarly, when a layer, an area, or an element is referred to as being “electrically connected” to another layer, area, or element, it may be directly electrically connected to the other layer, area, or element, and/or may be indirectly electrically connected with one or more intervening layers, areas, or elements therebetween. In addition, it will also be understood that when an element or layer is referred to as being “between” two elements or layers, it can be the only element or layer between the two elements or layers, or one or more intervening elements or layers may also be present.

The terminology used herein is for the purpose of describing particular embodiments and is not intended to be limiting of the present disclosure. As used herein, the singular forms “a” and “an” are intended to include the plural forms as well, unless the context clearly indicates otherwise. It will be further understood that the terms “comprises,” “comprising,” “includes,” “including,” “has,” “have,” and “having,” when used in this specification, specify the presence of the stated features, integers, steps, operations, elements, and/or components, but do not preclude the presence or addition of one or more other features, integers, steps, operations, elements, components, and/or groups thereof. As used herein, the term “and/or” includes any and all combinations of one or more of the associated listed items. For example, the expression “A and/or B” denotes A, B, or A and B. Expressions such as “at least one of,” when preceding a list of elements, modify the entire list of elements and do not modify the individual elements of the list. For example, the expression “at least one of a, b, or c,” “at least one of a, b, and c,” and “at least one selected from the group consisting of a, b, and c” indicates only a, only b, only c, both a and b, both a and c, both b and c, all of a, b, and c, or variations thereof.

As used herein, the term “substantially,” “about,” and similar terms are used as terms of approximation and not as terms of degree, and are intended to account for the inherent variations in measured or calculated values that would be recognized by those of ordinary skill in the art. Further, the use of “may” when describing embodiments of the present disclosure refers to “one or more embodiments of the present disclosure.” As used herein, the terms “use,” “using,” and “used” may be considered synonymous with the terms “utilize,” “utilizing,” and “utilized,” respectively.

Unless otherwise defined, all terms (including technical and scientific terms) used herein have the same meaning as commonly understood by one of ordinary skill in the art to which the present disclosure belongs. It will be further understood that terms, such as those defined in commonly used dictionaries, should be interpreted as having a meaning that is consistent with their meaning in the context of the relevant art and/or the present specification, and should not be interpreted in an idealized or overly formal sense, unless expressly so defined herein.

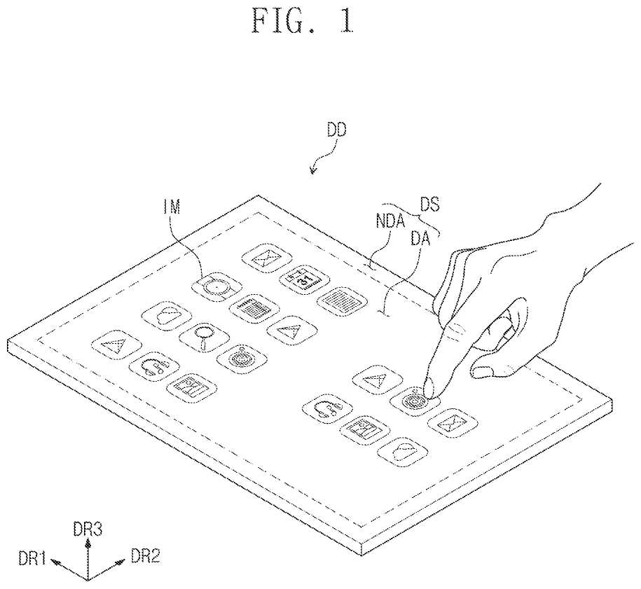

FIG. 1 is a perspective view of a display device according to an embodiment of the present disclosure.

Referring to FIG. 1, the display device DD according to an embodiment of the present disclosure may have a rectangular shape with long sides extending in a first direction DR1, and short sides extending in a second direction DR2 crossing the first direction DR1. However, the present disclosure is not limited thereto, and the display device DD may have various suitable shapes, such as a circular shape or another polygonal shape.

Hereinafter, a direction that is perpendicular to or substantially perpendicular to a plane defined by the first and second directions DR1 and DR2 is defined as a third direction DR3. In addition, as used herein, the expressions “when viewed on a plane” and “in a plan view” may refer to a state of being viewed in the third direction DR3.

The upper surface of the display device DD may be defined as a display surface DS, and may have a plane defined by the first and second directions DR1 and DR2. Images IM generated by the display device DD may be provided to a user through the display surface DS.

The display surface DS may include a display region DA, and a non-display region NDA around (e.g., adjacent to) the display region DA. The display region DA may display an image, and the non-display region NDA may not display an image. The non-display region NDA may surround (e.g., around a periphery of) the display region DA, and may define an edge of the display device DD, which may be printed in a suitable color (e.g., a predetermined color).

The display device DD may be used for large electronic devices, such as televisions, monitors, or external billboards. In addition, the display device DD may be used for small- and medium-sized electronic devices, such as personal computers, notebook computers, personal digital terminals, car navigation systems, game consoles, smart phones, tablets, or cameras. However, the present disclosure is not limited thereto, and the display device DD may be used for any other suitable electronic devices that display images to a user.

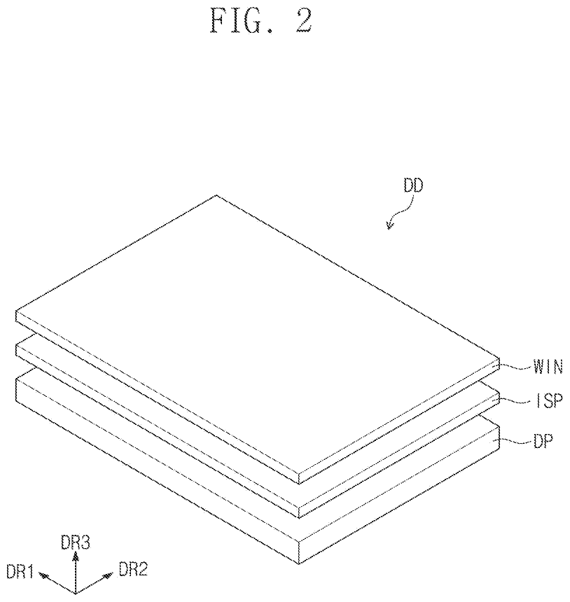

FIG. 2 is an exploded perspective view of the display device illustrated in FIG. 1.

Referring to FIG. 2, the display device DD may include a display panel DP, an input sensor ISP disposed on the display panel DP, and a window WIN disposed on the input sensor ISP.

The display panel DP according to an embodiment of the present disclosure may be a light-emitting display panel, but is not particularly limited thereto. For example, the display panel DP may be an organic light-emitting display panel or a quantum dot light-emitting display panel. A light-emitting layer of the organic light-emitting display panel may contain an organic light-emitting material. A light-emitting layer of the quantum dot light-emitting display panel may contain quantum dots, quantum rods, and/or the like. Hereinafter, for convenience, the display panel DP will be described in more detail in the context of the organic light-emitting display panel, but the present disclosure is not limited thereto.

The window WIN may protect the display panel DP and the input sensor ISP from external scratches and impacts. The window WIN may be attached to the input sensor ISP by an adhesive. The adhesive may include various suitable adhesives, such as an optical clear adhesive or a pressure sensitive adhesive. An image generated by the display panel DP may be transmitted through the window WIN and provided to a user.

The input sensor ISP may be manufactured directly on the display panel DP when a display module DM (e.g., a touch-display) is manufactured. However, the present disclosure is not limited thereto, and the input sensor ISP may be manufactured as an input sensing panel separate from the display panel DP, and attached to the display panel DP by an adhesive.

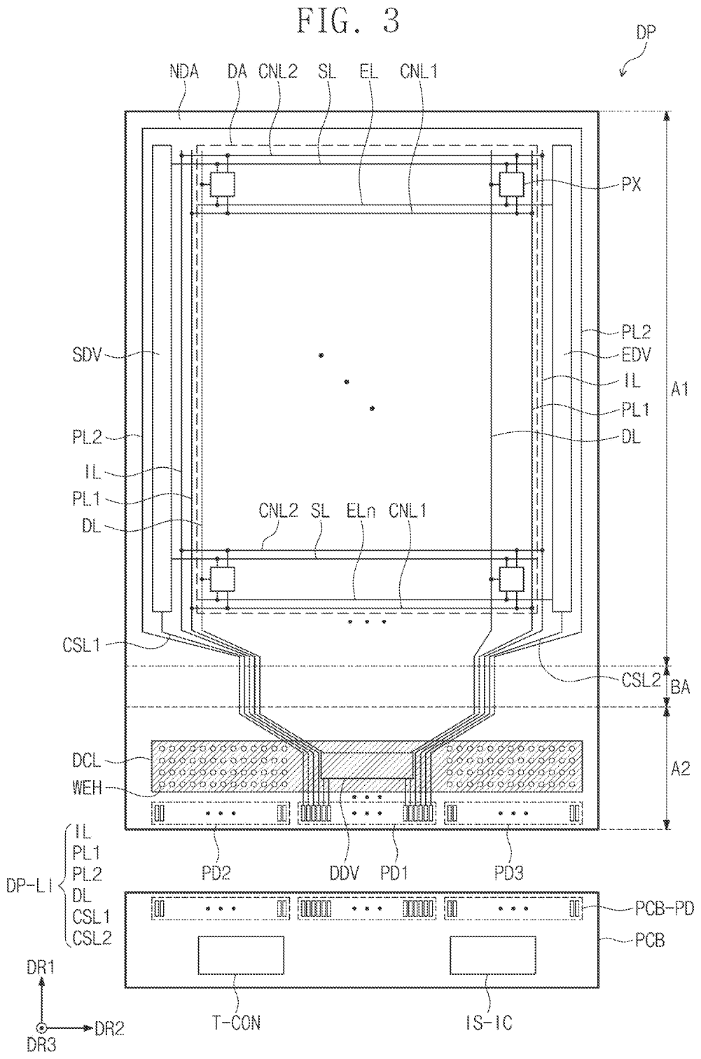

FIG. 3 is a plan view of the display panel illustrated in FIG. 2.

Referring to FIG. 3, the display device DD may include the display panel DP, a scan driver SDV, a data driver DDV, a light-emitting driver EDV, a printed circuit board PCB, a timing controller T-CON, a driving cover layer DCL, and an input sensing controller IS-IC.

The display panel DP may be a flexible display panel. For example, the display panel DP may include a plurality of electronic elements disposed on a flexible substrate. The display panel DP may have a rectangular shape with long sides extending in the first direction DR1 and short sides extending in the second direction DR2.

The display panel DP may include a first region A1, a second region A2, and a bending region BA between the first region A1 and the second region A2. The first region A1, the bending region BA, and the second region A2 may be arranged along the first direction DR1, and the bending region BA may extend in the second direction DR2.

The first region A1 may include a display region DA, and a non-display region NDA around (e.g., adjacent to) the display region DA. The non-display region NDA may surround (e.g., around a periphery of) the display region DA. The display region DA may display an image, and the non-display region NDA may not display an image. A region which does not display an image may be defined as a bezel region. When the bending region BA is bent, the second region A2 may be disposed below (e.g., underneath) the first region A1.

The display panel DP may include a plurality of pixels PX, a plurality of scan lines SL, a plurality of data lines DL, a plurality of light-emitting lines EL, first and second control lines CSL1 and CSL2, a plurality of initialization lines IL, a plurality of first power lines PL1, a second power line PL2, a plurality of first connection lines CNL1, a plurality of second connection lines CNL2, and a plurality of pads PD1, PD2, and PD3.

The pixels PX may be disposed in the display region DA. The scan driver SDV, the data driver DDV, and the light-emitting driver EDV may be disposed in the non-display region NDA. The scan driver SDV and the light-emitting driver EDV may be disposed to be adjacent to the long sides, respectively, of the display panel DP in the non-display region NDA.

The data driver DDV may be manufactured in the form of an integrated circuit chip, and may be disposed in the second region A2. However, the present disclosure is not limited thereto, and the data driver DDV may be mounted on a flexible circuit board connected to the display panel DP, and may be connected to the display panel DP through the flexible circuit board. The data driver DDV may be defined as a driving chip.

The scan lines SL may extend in the second direction DR2 to be connected to the pixels PX and the scan driver SDV. The data lines DL may extend in the first direction DR1 to be connected to the pixels PX and the data driver DDV. The light-emitting lines EL may extend in the second direction DR2 to be connected to the pixels PX and the light-emitting driver EDV.

The first power lines PL1 may extend in the first direction DR1, and may be disposed in the non-display region NDA. The first power lines PL1 may receive a first voltage. The first connection lines CNL1 may extend in the second direction DR2 to be connected to the first power lines PL1 and the pixels PX. The first voltage may be applied to the pixels PX through the first power lines PL1 and the first connection lines CNL1 that are connected to each other.

The initialization lines IL may extend in the first direction DR1, and may be disposed in the non-display region NDA. The initialization lines IL may receive an initialization voltage. The second connection lines CNL2 may extend in the second direction DR2 to be connected to the initialization lines IL and the pixels PX. The initialization voltage may be applied to the pixels PX through the initialization lines IL and the second connection lines CNL2 that are connected to each other. The pixels PX may be initialized by the initialization voltage.

The second power line PL2 may extend along an edge of the first region A1. The second power line PL2 may receive a second voltage. The second voltage may have a lower level than that of the first voltage. The second voltage may be provided to the pixels PX through the second power line PL2.

The first control line CSL1 may be connected to the scan driver SDV. The second control line CSL2 may be connected to the light-emitting driver EDV.

The pads PD1, PD2, and PD3 may be disposed on one side of the display panel DP. The pads PD1, PD2, and PD3 may be disposed in the second region A2. The pads PD1, PD2, and PD3 may include a plurality of first pads PD1, a plurality of second pads PD2, and a plurality of third pads PD3. The first pads PD1 may be disposed between the second pads PD2 and the third pads PD3.

The data lines DL, the first and second control lines CSL1 and CSL2, the initialization lines IL, the first power lines PL1, and the second power line PL2 may be defined as panel lines DP-LI. The panel lines DP-LI may be connected to the first pads PD1. In more detail, the data lines DL, the first and second control lines CSL1 and CSL2, the initialization lines IL, the first power lines PL1, and the second power line PL2 may be connected to the first pads PD1 in the second region A2 via the bending region BA.

The data lines DL may be connected to corresponding first pads PD1 from among the first pads PD1 through the data driver DDV. For example, the data lines DL may be connected to the data driver DDV, and the data driver DDV may be connected to the corresponding first pads PD1 corresponding to the data lines DL. The data lines DL may be connected to or substantially connected to the pixels PX and the data driver DDV, and the data lines DL may be also connected to the data driver DDV and the first pads PD1.

The second pads PD2 and the third pads PD3 may be connected to sensing lines of the input sensor ISP (e.g., see FIG. 2), which will be described in more detail below.

The timing controller T-CON and the input sensing controller IS-IC may be disposed on the printed circuit board PCB. Each of the timing controller T-CON and the input sensing controller IS-IC may be manufactured as an integrated circuit chip, and mounted on the printed circuit board PCB.

A plurality of pads PCB-PD may be disposed on one side of the printed circuit board PCB. The pads PCB-PD may be connected to the first, second, and third pads PD1, PD2, and PD3. In some embodiments, the flexible circuit board may be connected to the printed circuit board PCB and the display panel DP, and the pads PCB-PD of the printed circuit board PCB may be connected to the first, second, and third pads PD1, PD2, and PD3 of the display panel DP through the flexible circuit board.

The timing controller T-CON may control the operation of the scan driver SDV, the data driver DDV, and the light-emitting driver EDV. The timing controller T-CON may generate a scan control signal, a data control signal, and a light-emitting control signal in response to control signals received from the outside.

The scan control signal may be provided to the scan driver SDV through the first control line CSL1. The light-emitting control signal may be provided to the light-emitting driver EDV through the second control line CSL2. The data control signal may be provided to the data driver DDV. The timing controller T-CON may receive image signals from the outside, convert a data format of the image signals so as to meet the interface specification of the data driver DDV, and provide the converted image signals to the data driver DDV.

The scan driver SDV may generate a plurality of scan signals in response to the scan control signal. The scan signals may be applied to the pixels PX through the scan lines SL. The scan signals may be sequentially applied to the pixels PX.

The data driver DDV may generate a plurality of data voltages corresponding to the image signals in response to the data control signal. The data voltages may be applied to the pixels PX through the data lines DL. The light-emitting driver EDV may generate a plurality of light-emitting signals in response to the light-emitting control signal. The light-emitting signals may be applied to the pixels PX through the light-emitting lines EL.

The pixels PX may receive the data voltages in response to the scan signals. The pixels PX may display an image by emitting light having a desired luminance corresponding to the data voltages in response to the light-emitting signals. A light-emitting time of the pixels PX may be controlled by the light-emitting signals.

The driving cover layer DCL may be disposed on the second region A2. The driving cover layer DCL may be disposed on the data driver DDV. The driving cover layer DCL may be disposed on portions of the data lines DL, the first and second control lines CSL1 and CSL2, the initialization lines IL, the first power lines PL1, and the second power line PL2.

When viewed on a plane (e.g., in a plan view), the driving cover layer DCL may extend in the second direction DR2. When viewed on a plane (e.g., in a plan view), the width of the driving cover layer DCL in the second direction DR2 may be greater than the width of the data driver DDV in the second direction DR2. When viewed on a plane (e.g., in a plan view), the width of the driving cover layer DCL in the first direction DR1 may be greater than the width of the data driver DDV in the first direction DR1. Accordingly, the driving cover layer DCL may cover the data driver DDV.

A plurality of openings WEH may be defined in (e.g., may penetrate) the driving cover layer DCL. When viewed on a plane (e.g., in a plan view), the openings WEH may be defined to be adjacent to opposite sides of the data driver DDV, which are opposite to each other in the second direction DR2. The openings WEH may not overlap with the data driver DDV.

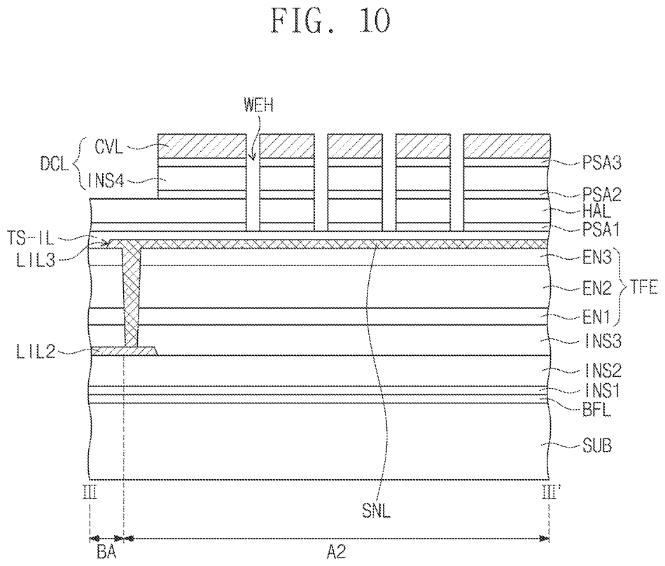

When moisture enters from the outside and is introduced between the display panel DP and the driving cover layer DCL, the moisture may be evaporated to the outside through the openings WEH. This will be described in more detail below with reference to FIG. 10.

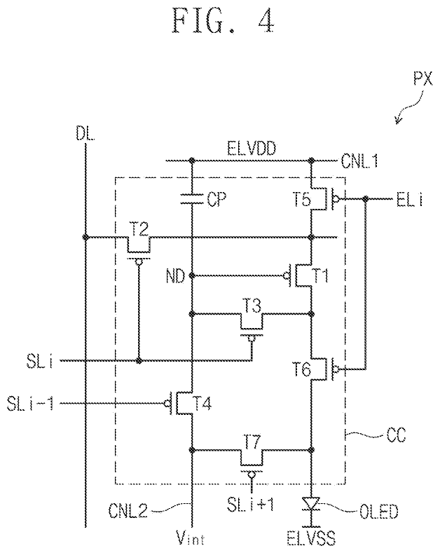

FIG. 4 illustrates an equivalent circuit of a pixel illustrated in FIG. 3. The pixel of FIG. 4 may correspond to any one of the pixels PX illustrated in FIG. 3. In other words, each of the pixels PX in FIG. 3 may have the same or substantially the same equivalent circuit of the pixel PX illustrated in FIG. 4.

Referring to FIG. 4, the pixel PX may include a light-emitting element OLED and a pixel circuit CC. The pixel circuit CC may include a plurality of transistors T1 to T7, and a capacitor CP. The pixel circuit CC may control an amount of current flowing through the light-emitting element OLED in response to a data voltage.

The light-emitting element OLED may emit light having a desired luminance (e.g., a predetermined luminance) corresponding to the amount of current provided from the pixel circuit CC. As such, the level of a first voltage ELVDD may be set higher than that of a second voltage ELVSS.

Each of the transistors T1 to T7 may include an input electrode (e.g., a source electrode), an output electrode (e.g., a drain electrode), and a control electrode (e.g., a gate electrode). Hereinafter, for convenience, any one of the input electrode and the output electrode may be referred to as a first electrode, and the other one may be referred to as a second electrode.

The first electrode of the first transistor T1 may receive the first voltage ELVDD via the fifth transistor T5, and the second electrode thereof may be connected to the anode electrode of the light-emitting element OLED via the sixth transistor T6. The first transistor T1 may be defined as a driving transistor. The first transistor T1 may control the amount of current flowing through the light-emitting element OLED according to a voltage applied to the control electrode of the first transistor T1.

The second transistor T2 may be connected between the data line DL and the first electrode of the first transistor T1, and the control electrode of the second transistor T2 may be connected to an i-th scan line SLi. The second transistor T2 may be turned on by receiving an i-th scan signal through the i-th scan line SLi, and electrically connect the data line DL and the first electrode of the first transistor T1 to each other.

The third transistor T3 may be connected between the second electrode of the first transistor T1 and the control electrode of the first transistor T1. The control electrode of the third transistor T3 may be connected to the i-th scan line SLi. The third transistor T3 may be turned on by receiving the i-th scan signal through the i-th scan line SLi, and electrically connect the second electrode and the control electrode of the first transistor T1 to each other. When the third transistor T3 is turned on, the first transistor T1 may be connected in a diode form (e.g., may be diode-connected).

The fourth transistor T4 may be connected between a node ND and the second connection line CNL2 connected to the initialization line IL. The control electrode of the fourth transistor T4 may be connected to an (i−1)-th scan line SLi−1. The fourth transistor T4 may be turned on by receiving an (i−1)-th scan signal through the (i−1)-th scan line SLi−1, and provide an initialization voltage Vint to the node ND. The initialization voltage Vint may be provided to the fourth transistor T4 through the initialization line IL and the second connection line CNL2.

The fifth transistor T5 may be connected between the first connection line CNL1 connected to the first power line PL1 and the first electrode of the first transistor T1. The control electrode of the fifth transistor T5 may be connected to an i-th light-emitting line ELi.

The sixth transistor T6 may be connected between the second electrode of the first transistor T1 and the anode electrode of the light-emitting element OLED. The control electrode of the sixth transistor T6 may be connected to the i-th light-emitting line ELi.

The seventh transistor T7 may be connected between the second connection line CNL2 and the anode electrode of the light-emitting element OLED. The control electrode of the seventh transistor T7 may be connected to an (i+1)-th scan line SLi+1. The seventh transistor T7 may be turned on by receiving an (i+1)-th scan signal through the (i+1)-th scan line SLi+1, and provide the initialization voltage Vint to the anode electrode of the light-emitting element OLED.

The capacitor CP may be disposed between the first connection line CNL1 and the node ND. The capacitor CP may store a data voltage. When the fifth transistor T5 and the sixth transistor T6 are turned on, the amount of current flowing through the first transistor T1 may be determined according to a voltage stored in the capacitor CP.

In FIG. 4, the transistors T1 to T7 are illustrated based on PMOS transistors, but the present disclosure is not limited thereto, and in another embodiment, at least some or all of the transistors T1 to T7 may be formed of NMOS transistors.

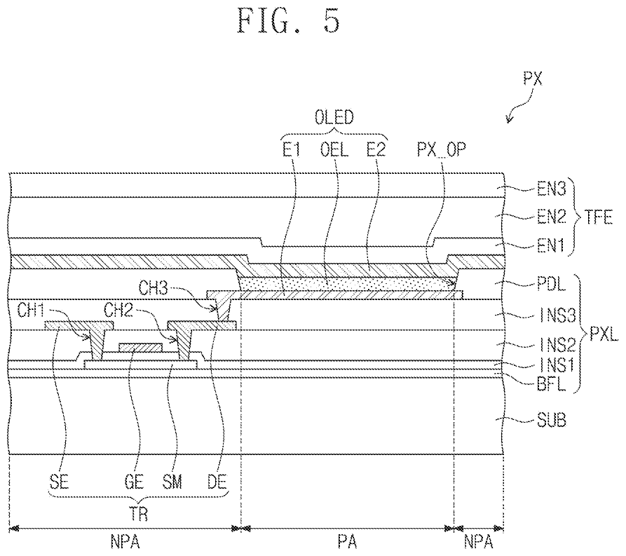

FIG. 5 is a cross-sectional view of a portion corresponding to the light-emitting element illustrated in FIG. 4.

Referring to FIG. 5, the pixel PX may include the light-emitting element OLED, and a transistor TR connected to the light-emitting element OLED. The light-emitting element OLED may include a first electrode E1, a second electrode E2, and an organic light-emitting layer OEL disposed between the first electrode E1 and the second electrode E2. The transistor TR may be the sixth transistor T6 illustrated in FIG. 4. The light-emitting element OLED may be defined as an organic light-emitting element.

The first electrode E1 may be an anode electrode, and the second electrode E2 may be a cathode electrode. The first electrode E1 may be defined as a pixel electrode, and the second electrode E2 may be defined as a common electrode.

The pixel PX may be divided into a pixel region PA, and a non-pixel region NPA around (e.g., adjacent to) the pixel region PA. The light-emitting element OLED may be disposed in the pixel region PA, and the transistor TR may be disposed in the non-pixel region NPA.

The transistor TR and the light-emitting element OLED may be disposed on a substrate SUB. A buffer layer BFL may be disposed on the substrate SUB, and the buffer layer BFL may contain an inorganic material.

A semiconductor layer SM of the transistor TR may be disposed on the buffer layer BFL. The semiconductor layer SM may include an organic semiconductor or an inorganic semiconductor, such as amorphous silicon or polycrystalline silicon. As another example, the semiconductor layer SM may include an oxide semiconductor. The semiconductor layer SM may include a source region, a drain region, and a channel region between the source region and the drain region.

A first insulating layer INS1 may be disposed on the buffer layer BFL to cover the semiconductor layer SM. The first insulating layer INS1 may contain an inorganic material. A gate electrode GE of the transistor TR overlapping with the semiconductor layer SM may be disposed on the first insulating layer INS1. The gate electrode GE may be disposed to overlap with the channel region of the semiconductor layer SM.

A second insulating layer INS2 may be disposed on the first insulating layer INS1 to cover the gate electrode GE. The second insulating layer INS2 may contain an organic material and/or an inorganic material.

The source electrode SE and the drain electrode DE of the transistor TR may be disposed to be spaced apart from each other on the second insulating layer INS2. The source electrode SE may be connected to the source region of the semiconductor layer SM through a first contact hole CH1 defined in (e.g., penetrating) the first and second insulating layers INS1 and INS2. The drain electrode DE may be connected to the drain region of the semiconductor layer SM through a second contact hole CH2 defined in (e.g., penetrating) the first and second insulating layers INS1 and INS2.

A third insulating layer INS3 may be disposed on the second insulating layer INS2 to cover the source electrode SE and the drain electrode DE of the transistor TR. The third insulating layer INS3 may be defined as a planarization film configured to provide a flat or substantially flat upper surface, and may contain an organic material.

The first electrode E1 may be disposed on the third insulating layer INS3. The first electrode E1 may be connected to the drain electrode DE of the transistor TR through a third contact hole CH3 defined in (e.g., penetrating) the third insulating layer INS3.

A pixel defining film PDL exposing a portion of the first electrode E1 may be disposed on the first electrode E1 and the third insulating layer INS3. An opening PX_OP for exposing a portion of the first electrode E1 may be defined in the pixel defining film PDL.

The organic light-emitting layer OEL may be disposed on the first electrode E1 in the opening PX_OP. The organic light-emitting layer OEL may generate any suitable one of red light, green light, or blue light. However, the present disclosure is not limited thereto, and the organic light-emitting layer OEL may generate white light by a combination of organic materials that generate red light, green light, and blue light.

The second electrode E2 may be disposed on the pixel defining film PDL and the organic light-emitting layer OEL. A thin film encapsulation layer TFE may be disposed on the pixel PX to cover the light-emitting element OLED. A layer between the substrate SUB and the thin film encapsulation layer TFE may be defined as a pixel layer PXL.

The thin film encapsulation layer TFE may include a first encapsulation layer EN1 disposed on the light-emitting element OLED, a second encapsulation layer EN2 disposed on the first encapsulation layer EN1, and a third encapsulation layer EN3 disposed on the second encapsulation layer EN2. Each of the first and third encapsulation layers EN1 and EN3 may contain an inorganic material, and the second encapsulation layer EN2 may contain an organic material. The thickness of the second encapsulation layer EN2 may be greater than that of each of the first and third encapsulation layers EN1 and EN3.

The first voltage ELVDD (e.g., see FIG. 4) may be applied to the first electrode E1, and the second voltage ELVSS may be applied to the second electrode E2. Holes and electrons injected into the organic light-emitting layer OEL may be combined with each other to form excitons, and while the excitons transition to a ground state, the light-emitting element OLED may emit light. The light-emitting element OLED may display an image by emitting red light, green light, and/or blue light according to the flow of a current.

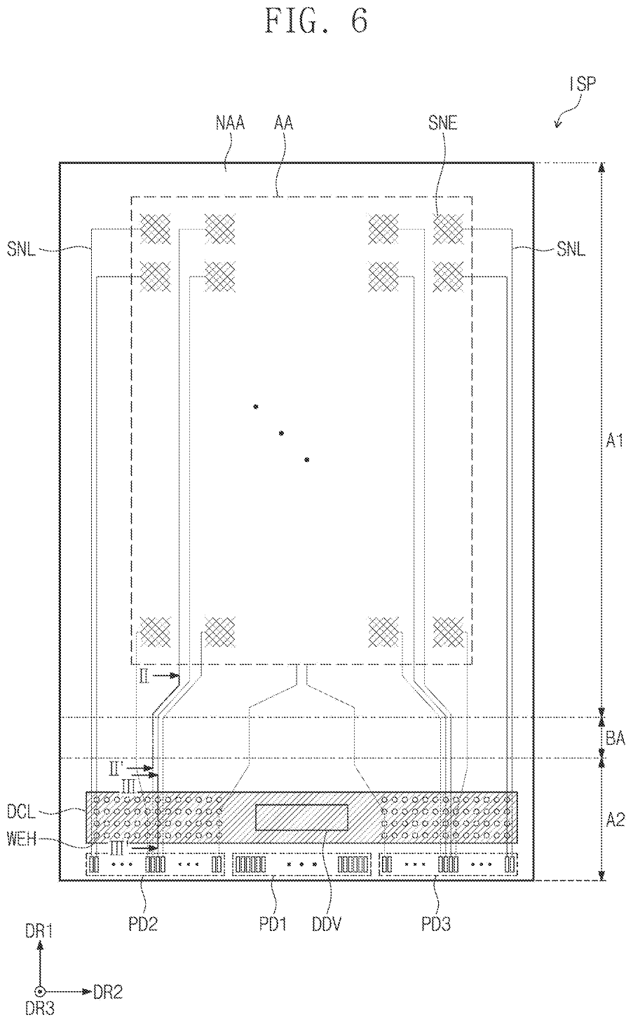

FIG. 6 is a plan view of an input sensor illustrated in FIG. 2.

Because a data driver DDV and a driving cover layer DCL illustrated in FIG. 6 are the same or substantially the same as the data driver DDV and the driving cover layer DCL described above with reference to FIG. 3, redundant description thereof may not be repeated or may be simplified.

Referring to FIGS. 3 and 6, the input sensor ISP may include a plurality of sensing electrodes SNE and a plurality of sensing lines SNL. The sensing electrodes SNE and the sensing lines SNL may be disposed on the thin film encapsulation layer TFE (e.g., see FIG. 5). The data driver DDV and the first, second, and third pads PD1, PD2, and PD3 illustrated in FIG. 6 may be the same or substantially the same as the data driver DDV and the first, second, and third pads of the display panel DP illustrated in FIG. 3.

Like the display panel DP, the input sensor ISP may include a first region A1, a second region A2, and a bending region BA between the first region A1 and the second region A2. The first region A1 may include an active region AA, and a non-active region NAA surrounding (e.g., around a periphery of) the active region AA. The active region AA may overlap with the display region DA, and the non-active region NAA may overlap with the non-display region NDA.

The sensing electrodes SNE may be disposed in the active region AA. The sensing electrodes SNE may be disposed on the first region A1. The sensing lines SNL may be connected to the sensing electrodes SNE. The sensing lines SNL may extend to the second region A2 via the non-active region NAA and the bending region BA. The sensing lines SNL may extend in the first direction DR1 by passing both sides of the data driver DDV, which are opposite to each other in the second direction DR2. The sensing lines SNL may be connected to the second and third pads PD2 and PD3 disposed in the second region A2.

The second and third pads PD2 and PD3 may be connected to the input sensing controller IS-IC of the printed circuit board PCB illustrated in FIG. 3. The input sensing controller IS-IC may control the operation of the input sensor ISP.

The sensing electrodes SNE may have unique coordinate information. For example, the sensing electrodes SNE may be arranged in a matrix form, and connected to the sensing lines SNL, respectively. However, the arrangement of the sensing electrodes SNE is not particularly limited thereto.

The input sensor ISP according to an embodiment of the present disclosure may be driven in a self-sensing mode to obtain coordinate information in a self-capacitance method. For example, the input sensing controller IS-IC may operate each of the sensing electrodes SNE as a driving electrode and a sensing electrode. The input sensing controller IS-IC may apply a driving signal to the sensing electrodes SNE through the sensing lines SNL, and may receive a sensing signal from each of the sensing electrodes SNE.

However, the present disclosure is not limited to the structure of the input sensor ISP illustrated in FIG. 6. For example, the input sensor ISP may include a plurality of first sensing electrodes and a plurality of second sensing electrodes to have a structure in which the input sensor ISP is driven in a mutual sensing mode. Capacitances may be formed by the first sensing electrodes and the second sensing electrodes.

The second sensing electrodes may extend to cross and be insulated from the first sensing electrodes. In the mutual sensing mode, the first sensing electrodes may be operated as driving electrodes, and the second sensing electrodes may be operated as sensing electrodes. The first sensing electrodes may be disposed at (e.g., in or on) the same layer as that of the second sensing electrodes, or at (e.g., in or on) a layer different from that of the second sensing electrodes.

The driving cover layer DCL may be disposed on portions of the sensing lines SNL and the data driver DDV. The driving cover layer DCL may cover portions of the sensing lines SNL and the data driver DDV.

When viewed on a plane (e.g., in a plan view), the openings WEH defined in the driving cover layer DCL may overlap with the sensing lines SNL. When moisture entering from the outside is introduced between the sensing lines SNL and the driving cover layer DCL, the moisture may be evaporated to the outside through the openings WEH. This will be described in more detail below with reference to FIG. 10.

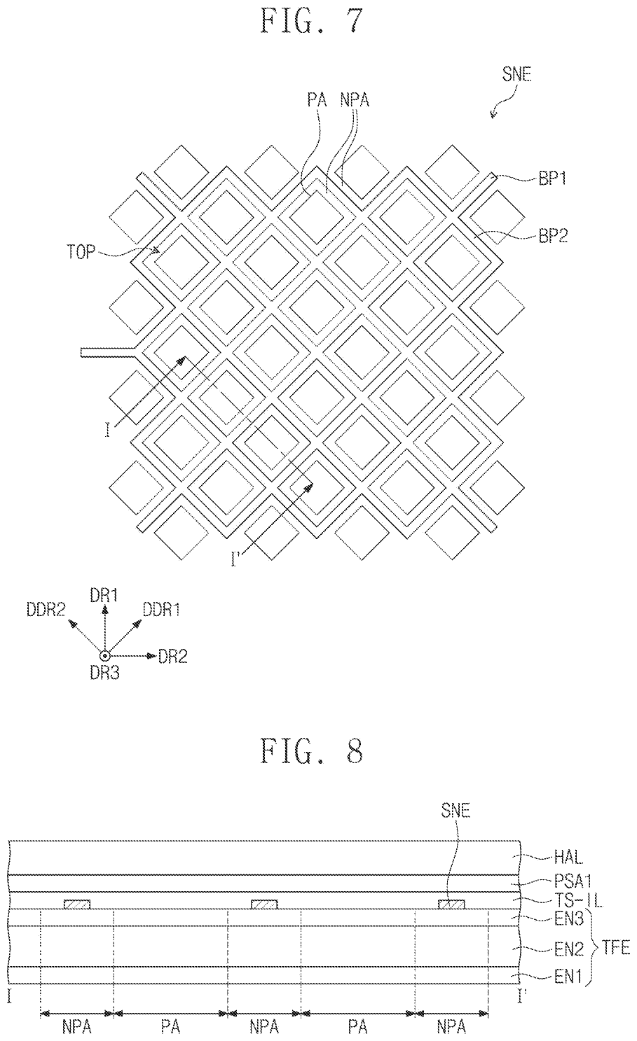

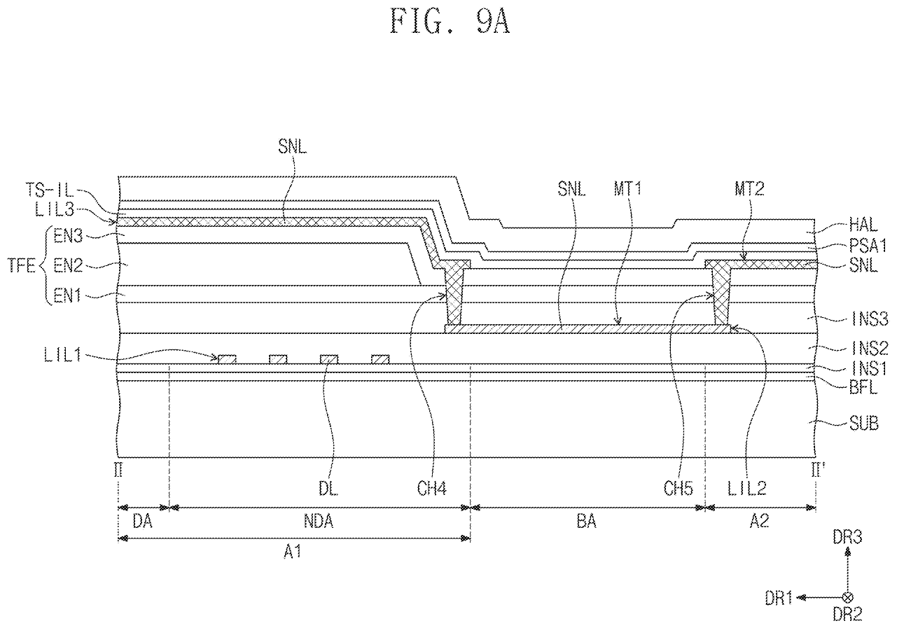

FIG. 7 shows a configuration of the sensing electrode illustrated in FIG. 6. FIG. 8 is a cross-sectional view taken along the line I-I′ illustrated in FIG. 7.

FIGS. 7 and 8 illustrate the pixel regions PA and the non-pixel region NPA together.

Referring to FIG. 7, the sensing electrode SNE may have a mesh shape. For example, the sensing electrode SNE may include a plurality of first branch portions BP1 extending in a first diagonal direction DDR1, and a plurality of second branch portions BP2 extending in a second diagonal direction DDR2.

The first diagonal direction DDR1 may be defined as a direction crossing the first and second directions DR1 and DR2 on a plane defined by the first and second directions DR1 and DR2. The second diagonal direction DDR2 may be defined as a direction crossing the first diagonal direction DDR1 on the plane defined by the first and second directions DR1 and DR2. For example, the first direction DR1 and the second direction DR2 may perpendicularly or substantially perpendicularly cross each other, and the first diagonal direction DDR1 and the second diagonal direction DDR2 may perpendicularly or substantially perpendicularly cross each other.

The first branch portions BP1 may cross the second branch portions BP2, and may be integrally formed with the second branch portions BP2. Sensing openings TOP having a diamond shape may be defined by the first branch portions BP1 and the second branch portions BP2 crossing each other. The first and second branch portions BP1 and BP2 may be defined by mesh lines, and a line width of each of the mesh lines may be about several micrometers. The first and second branch portions BP1 and BP2 may contain a metal.

The pixel regions PA may have a diamond shape, and may be disposed to overlap with the sensing openings TOP. The first and second branch portions BP1 and BP2 may be disposed to overlap with the non-pixel region NPA. The pixel region PA illustrated in FIG. 5 may be any one of the pixel regions PA illustrated in FIG. 7.

The pixel regions PA may be defined as light-emitting regions, and the non-pixel region NPA may be defined as a non-light-emitting region. Because the first and second branch portions BP1 and BP2 are disposed in the non-pixel region NPA, light generated in the pixel regions PA may be normally emitted without being affected by the first and second branch portions BP1 and BP2.

Referring to FIG. 8, the sensing electrode SNE may be disposed on the thin film encapsulation layer TFE. The sensing electrode SNE may be disposed directly on the thin film encapsulation layer TFE, so as to come in contact with the thin film encapsulation layer TFE. An insulating layer TS-IL may be disposed on the thin film encapsulation layer TFE to cover the sensing electrode SNE.

An insulating layer may be additionally disposed on the thin film encapsulation layer TFE. The first, second, and third encapsulation layers EN1, EN2, and EN3 may be insulating layers, and an additional insulating layer may be disposed on the third encapsulation layer EN3. In this case, the sensing electrode SNE may be disposed directly on the insulating layer (e.g., the additional insulating layer) disposed on the uppermost layer from among the plurality of insulating layers.

A cover layer HAL may be disposed above the insulating layer TS-IL. The cover layer HAL may be disposed above the sensing electrode SNE. The cover layer HAL may contain a silane compound for absorbing moisture. For example, the cover layer HAL may contain silica gel for absorbing moisture. The cover layer HAL will be described in more detail below with reference to FIG. 10.

A first adhesive layer PSA1 may be disposed between the insulating layer TS-IL and the cover layer HAL, and the insulating layer TS-IL and the cover layer HAL may be bonded to each other by the first adhesive layer PSA1.

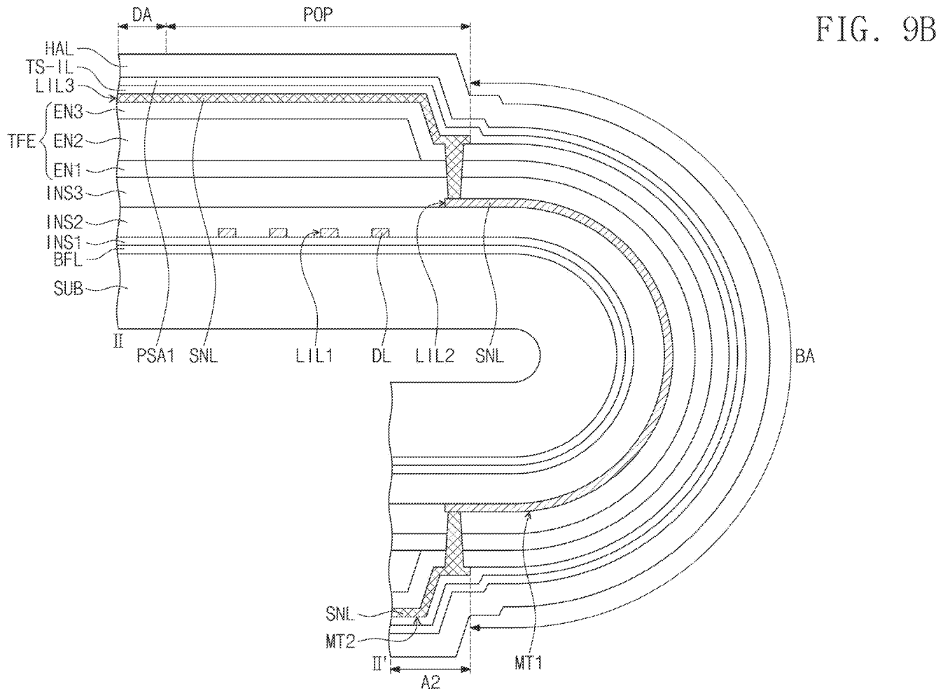

FIG. 9A is a cross-sectional view taken along the line II-II′ illustrated in FIG. 6. FIG. 9B illustrates a bent state of the bending region illustrated in FIG. 9A.

Hereinafter, a layer on the first insulating layer INS1 is defined as a first wiring layer LIL1, and a layer on the second insulating layer INS2 is defined as a second wiring layer LIL2. In addition, a layer on the thin film encapsulation layer TFE may be defined as a third wiring layer LIL3. The second wiring layer LIL2 may be disposed above the first wiring layer LIL1. The third wiring layer LIL3 may be disposed on the second wiring layer LIL2.

Referring to FIG. 9A, the first and third encapsulation layers EN1 and EN3 may extend from the first region A1 to the second region A2 through the bending region BA. The second encapsulation layer EN2 may be disposed in the first region A1. The second encapsulation layer EN2 may not be disposed in the bending region BA and the second region A2.

On the first region A1 adjacent to the boundary between the first region A1 and the bending region BA, the second encapsulation layer EN2 may have an inclined surface. The third encapsulation layer EN3 may extend along the inclined surface of the second encapsulation layer EN2. On the first region A1 adjacent to the boundary between the first region A1 and the bending region BA, the third encapsulation layer EN3 may have an inclined surface.

The data line DL may be disposed in the first wiring layer LIL1. The sensing line SNL may be disposed in the third wiring layer LIL3 in the first region A1, in the second wiring layer LIL2 in the bending region BA, and in the third wiring layer LIL3 in the second region A2.

The sensing line SNL extending from the first region A1 to the bending region BA may be disposed in the second wiring layer LIL2 in the bending region BA through a fourth contact hole CH4 defined in (e.g., penetrating) the first and third encapsulation layers EN1 and EN3 and the third insulating layer INS3. For example, the sensing line SNL disposed in the first region A1 may be connected to a first metal electrode MT1 disposed in the second wiring layer LIL2 in the bending region BA.

The sensing line SNL extending from the bending region BA to the second region A2 may be disposed in the third wiring layer LIL3 through a fifth contact hole CH5 defined in (e.g., penetrating) the first and third encapsulation layers EN1 and EN3 and the third insulating layer INS3. For example, the sensing line SNL disposed in the bending region BA may be connected to a second metal electrode MT2 disposed in the third wiring layer LIL3 in the second region A2.

The cover layer HAL may be disposed on the insulating layer TS-IL. The cover layer HAL may be disposed on the first region A1, the bending region BA, and the second region A2. The cover layer HAL may be disposed on the sensing line SNL.

The cover layer HAL may contain a silane compound for absorbing moisture. For example, the cover layer HAL may contain silica gel. However, the present disclosure is not limited thereto, and the cover layer HAL may contain octadecylchlorosilane, octachlorosilane, butylchlorosilane, cyanopropylchlorosilane, and/or phenylchlorosilane. Accordingly, the cover layer HAL may absorb moisture introduced from the outside. The cover layer HAL will be described in more detail below with reference to FIG. 10.

The first adhesive layer PSA1 may be disposed between the cover layer HAL and the insulating layer TS-IL, and the insulating layer TS-IL and the cover layer HAL may be bonded to each other by the first adhesive layer PSA1.

Referring to FIG. 9B, the bending region BA may be bent so that the second region A2 is disposed below (e.g., underneath) the first region A1. Stress may occur in the bending region BA. A greater compressive stress may occur in the first wiring layer LIL1 disposed further inside than the other wiring layers. When lines are disposed in the first wiring layer LIL1 or the third wiring layer LIL3 in the bending region BA, the lines may be damaged by compressive stress and tensile stress.

A greater compressive stress may occur in the first wiring layer LIL1 disposed further inside than the other wiring layers, and a greater tensile stress may occur in the third wiring layer LIL3 disposed further outside than the other wiring layers. Accordingly, when the sensing line SNL is disposed in the third wiring layer LIL3 in the bending region BA, the sensing line SNL may be damaged by the tensile stress.

However, according to one or more embodiments of the present disclosure, the sensing line SNL may be disposed in the second wiring layer LIL2 in the bending region BA. In this case, relatively smaller compressive stress and tensile stress may occur in the second wiring layer LIL2 than in the first wiring layer LIL1 or the third wiring layer LIL3. Accordingly, damage to the lines disposed in the second wiring layer LIL2 may be prevented or substantially prevented.

FIG. 10 is a cross-sectional view taken along the line III-III′ illustrated in FIG. 6.

A substrate SUB, a buffer layer BFL, first to third insulating layers INS1 to INS3, and a thin film encapsulation layer TFE illustrated in FIG. 10 are the same or substantially the same as the substrate SUB, the buffer layer BFL, the first to third insulating layers INS1 to INS3 and the thin film encapsulation layer TFE described above with reference to FIG. 5, and thus, redundant description thereof may not be repeated or may be simplified. In addition, first to third wiring layers LIL1 to LIL3, an insulating layer TS-IL, a sensing line SNL, a first adhesive layer PSA1, and a cover layer HAL illustrated in FIG. 10 are the same or substantially the same as the first to third wiring layers LIL1 to LIL3, the insulating layer TS-IL, the sensing line SNL, the first adhesive layer PSA1, and the cover layer HAL described above with reference to FIG. 9A, and thus, redundant description thereof may not be repeated or may be simplified.

Referring to FIG. 10, the cover layer HAL may be disposed on the sensing line SNL. The cover layer HAL may contain a silane compound for absorbing moisture. For example, the cover layer HAL may contain silica gel. However, the present disclosure is not limited thereto, and the cover layer HAL may contain octadecylchlorosilane, octachlorosilane, butylchlorosilane, cyanopropylchlorosilane, and/or phenylchlorosilane.

Moisture introduced from the outside may corrode the sensing line SNL containing a metal. When the sensing line SNL is corroded, the input sensor ISP shown in FIG. 6 may be damaged, thus making the display device DD defective.

However, because the cover layer HAL is disposed on the sensing line SNL, the cover layer HAL may absorb moisture introduced from the outside. Accordingly, moisture may not flow into the sensing line SNL. Therefore, the sensing line SNL is prevented or substantially prevented from being damaged, and the display device DD may be prevented or substantially prevented from being defective.

The driving cover layer DCL may be disposed on the cover layer HAL. The driving cover layer DCL may be disposed in the second region A2. The driving cover layer DCL may be disposed on the sensing line SNL.

The driving cover layer DCL may cover and protect the data driver DDV (e.g., see FIG. 6) and the sensing line SNL. In addition, the driving cover layer DCL may protect the data driver DDV from static electricity.

The driving cover layer DCL may include a fourth insulating layer INS4 and a cover portion CVL. The fourth insulating layer INS4 may be disposed on the cover layer HAL. The fourth insulating layer INS4 may contain phosphorus (P) or fluorine (F). In some embodiments, the fourth insulating layer INS4 may be composed of a plurality of layers.

The cover portion CVL may be disposed on the insulating layer INS4. As the cover portion CVL contains a black material, and thus, the data driver DDV may be prevented or substantially prevented from being viewed from the outside.

A second adhesive layer PSA2 may be disposed between the cover layer HAL and the fourth insulating layer INS4, and the cover layer HAL and the fourth insulating layer INS4 may be bonded to each other by the second adhesive layer PSA2.

A third adhesive layer PSA3 may be disposed between the fourth insulating layer INS4 and the cover portion CVL, and the fourth insulating layer INS4 and the cover portion CVL may be bonded to each other by the third adhesive layer PSA3.

The openings WEH may be defined by (e.g., may penetrate) the driving cover layer DCL and the cover layer HAL. The openings WEH may pass through the driving cover layer DCL and the cover layer HAL. The openings WEH may overlap with the sensing line SNL.

When moisture entering from the outside is introduced into the sensing line SNL, the sensing line SNL may be corroded. In addition, when phosphorus (P) or fluorine (F) contained in the fourth insulating layer INS4 is ionized by reacting with moisture, the sensing line SNL may be corroded. Accordingly, the display device DD (e.g., see FIG. 1) may become defective.

According to one or more embodiments of the present disclosure, when the openings WEH are defined by the driving cover layer DCL and the cover layer HAL, moisture introduced from the outside may be evaporated through the openings WEH. Accordingly, corrosion of the sensing line SNL may be prevented or substantially prevented. Therefore, the display device DD (e.g., see FIG. 1) may be prevented or substantially prevented from being defective.

According to one or more embodiments of the present disclosure, a plurality of openings may be defined in a driving cover layer covering a data driver and portions of sensing lines. In addition, a cover layer for absorbing moisture may be disposed between portions of the sensing lines and the driving cover layer. As the openings are defined and the cover layer is disposed, even though moisture may be introduced from the outside into the sensing lines, the moisture may be evaporated through the openings and/or absorbed by the cover layer, and therefore, corrosion of the sensing lines may be prevented or substantially prevented.

The foregoing is illustrative of some embodiments of the present disclosure, and is not to be construed as limiting thereof. Although some embodiments have been described, those skilled in the art will readily appreciate that various modifications are possible in the embodiments without departing from the spirit and scope of the present disclosure. It will be understood that descriptions of features or aspects within each embodiment should typically be considered as available for other similar features or aspects in other embodiments, unless otherwise described. Thus, as would be apparent to one of ordinary skill in the art, features, characteristics, and/or elements described in connection with a particular embodiment may be used singly or in combination with features, characteristics, and/or elements described in connection with other embodiments unless otherwise specifically indicated. Therefore, it is to be understood that the foregoing is illustrative of various example embodiments and is not to be construed as limited to the specific embodiments disclosed herein, and that various modifications to the disclosed embodiments, as well as other example embodiments, are intended to be included within the spirit and scope of the present disclosure as defined in the appended claims, and their equivalents.

1. A display device comprising:
a display panel comprising a first region, a second region, and a bending region located along a first direction, the bending region being between the first and second regions;
a plurality of sensing electrodes on the first region;
a data driver on the second region;
sensing lines on the first region connected to the sensing electrodes, and extending in the first direction toward opposite sides of the data driver opposite to each other in a second direction crossing the first direction; and
a cover layer on the sensing lines.

2. The display device of claim 1, wherein the cover layer comprises a silane compound to absorb moisture.

3. The display device of claim 1, further comprising a driving cover layer covering the data driver and portions of the sensing lines adjacent to the data driver.

4. The display device of claim 3, wherein the driving cover layer is located on the second region.

5. The display device of claim 3, wherein:
an opening is defined in the driving cover layer; and
the opening overlaps with portions of the sensing lines in a plan view.

6. The display device of claim 5, wherein the opening passes through the driving cover layer and the cover layer.

7. The display device of claim 5, wherein the opening is adjacent to the opposite sides of the data driver in a plan view.

8. The display device of claim 5, wherein the opening does not overlap with the data driver.

9. The display device of claim 3, wherein the driving cover layer comprises:
an insulating layer on the cover layer; and
a cover portion comprising a black material on the insulating layer.

10. The display device of claim 1, wherein the cover layer is located on the first region, the bending region, and the second region.

11. A display device comprising:
a display panel comprising a first region, a second region, and a bending region located along a first direction, the bending region being between the first and second regions;
a plurality of sensing electrodes on the first region;
a data driver on the second region;
sensing lines on the first region connected to the sensing electrodes, and extending in the first direction toward opposite sides of the data driver opposite to each other in a second direction crossing the first direction; and
a driving cover layer covering the data driver and portions of the sensing lines adjacent to the data driver,
wherein an opening overlapping with portions of the sensing lines in a plan view is defined in the driving cover layer.

12. The display device of claim 11, wherein the driving cover layer is located on the second region.

13. The display device of claim 12, wherein the opening is defined to be adjacent to the opposite sides of the data driver in a plan view.

14. The display device of claim 13, wherein the opening does not overlap with the data driver in a plan view.

15. The display device of claim 11, further comprising a cover layer between the sensing lines and the driving cover layer.

16. The display device of claim 15, wherein the cover layer comprises a silane compound to absorb moisture.

17. The display device of claim 15, wherein the opening passes through the cover layer and the driving cover layer.

18. The display device of claim 15, wherein the cover layer is located on the first region, the bending region, and the second region.

19. The display device of claim 11, wherein the driving cover layer comprises:
an insulating layer on the data driver; and
a cover portion comprising a black material on the insulating layer.

20. The display device of claim 11, wherein, when the bending region is bent, a portion located in the bending region of a sensing line from among the sensing lines is located more inward than other portions of the sensing line located in the first and second regions.
